(19) United States
(12) Patent Application Publication
(10) Pub. No.: US 2014/0091829 A1
(43) Pub. Date: Apr. 3, 2014

(54) SEMICONDUCTOR DEVICE, APPARATUS OF ESTIMATING LIFETIME, METHOD OF ESTIMATING LIFETIME

(71) Applicant: Kabushiki Kaisha Toshiba, Tokyo (JP)

(72) Inventors: Yuu YAMAYOSE, Tokyo (JP); Kenji HIROHATA, Tokyo (JP)

(73) Assignee: Kabushiki Kaisha Toshiba, Tokyo (JP)

(21) Appl. No.: 14/013,573

(22) Filed: Aug. 29, 2013

(30) Foreign Application Priority Data
Sep. 28, 2012 (JP) 2012-218786

(51) Int. Cl. G01R 31/319

(52) U.S. Cl. CPC G01R 31/31924
USPC 324/762.01

(57) ABSTRACT

According to one embodiment, a semiconductor device includes a circuit board, a plurality of semiconductor chips stacked above the circuit board, first and second bumps, third and fourth bumps, and first and second detection units. The first and second bumps are provided in either a gap between the circuit board and the semiconductor chip or a gap between the two semiconductor chips. The third and fourth bumps are provided in any of gaps other than the gap in which the first and second bumps are provided. The first detection unit is electrically connected to the first bump to detect damage of the first bump and to generate a first signal indicating the damage of the first bump. The second detection unit is electrically connected to the third bump to detect damage of the third bump and to generate a second signal indicating the damage of the third bump.

### CROSS REFERENCE TO RELATED APPLICATION

This application is based upon and claims the benefit of priority from the prior Japanese Patent Application No. 2012-218786, filed on Sep. 28, 2012, the entire contents of which are incorporated herein by reference.

### FIELD

Embodiments described herein relate generally to a semiconductor device, an apparatus of estimating a lifetime, and a method of estimating a lifetime.

### BACKGROUND

In a stacked semiconductor device (hereinafter, referred to as a semiconductor device), two or more semiconductor chips are stacked above a circuit board. The circuit board and the lowermost-layer chip are interconnected through bumps. The lowermost semiconductor chip and the semiconductor chip stacked above the lowermost-layer chip are interconnected through bumps. When the semiconductor device is used for a long time, cracks gradually occur in the bumps.

The occurrence of cracks in the bumps leads to failure of the semiconductor device. Since the crack occurring in early stage is equivalent to a symptom of failure of the semiconductor device, or failure itself, it is preferable that the crack occurring at early stage be detected as early as possible.

However, since property of stress mainly occurring in bumps and the stressed areas appear differently according to stiffness of a circuit board or the packaging conditions of a semiconductor device, it is difficult to specify the positions of the bumps where cracks occur in early stage in advance.

### BRIEF DESCRIPTION OF THE DRAWINGS

FIG. 1 is a diagram illustrating a semiconductor device according to a first embodiment;

FIG. 2 is a cross-sectional diagram illustrating the semiconductor device according to the first embodiment (A-A);

FIG. 3 is a cross-sectional diagram illustrating the semiconductor device according to the first embodiment (B-B);

FIG. 4 is a cross-sectional diagram illustrating the semiconductor device according to the first embodiment (C-C);

FIG. 5 is a diagram illustrating a semiconductor device according to a second embodiment;

FIG. 6 is a flowchart illustrating operations of a load estimation unit according to the second embodiment;

FIG. 7 is a diagram illustrating a semiconductor device according to a comparative example; and FIG. 8 is a cross-sectional diagram illustrating the semiconductor device according to the comparative example (D-D).

### DETAILED DESCRIPTION

According to one embodiment, a semiconductor device includes a circuit board, a plurality of semiconductor chips, first and second bumps, and third and fourth bumps. The plurality of semiconductor chips is stacked above the circuit board. The first and second bumps are provided in either a gap between the circuit board and the semiconductor chip or a gap between the two semiconductor chips. The second bump is more distant from a peripheral portion of the semiconductor chip than the first bump. The third and fourth bumps are provided in any of gaps other than the gap in which the first and second bumps are provided among the gaps including the gap between the circuit board and the semiconductor chip and the gap between the two semiconductor chips. The fourth bump is more distant from a peripheral portion of the semiconductor chip than the third bump. A first detection unit is electrically connected to the first bump to detect damage of the first bump and to generate a first signal indicating the damage of the first bump. A second detection unit is electrically connected to the third bump to detect damage of the third bump and to generate a second signal indicating the damage of the third bump.

According to another embodiment, an apparatus of estimating a lifetime of a semiconductor device as described above includes a load estimation unit and a lifetime estimation unit. The load estimation unit is configured to receive a first signal indicating damage of the first bump and a second signal indicating damage of the third bump and to calculate the difference between reception times of the first and second signals to estimate a load state of the second or fourth bump based on the time difference. The lifetime estimation unit is configured to estimate a lifetime of the second or fourth bump based on the load state.

According to another embodiment, a method of estimating a lifetime of a semiconductor device as described above includes: receiving a first signal indicating damage of the first bump and a second signal indicating damage of the third bump and calculating the difference between reception times of the first and second signals to estimate a load state of the second or fourth bump based on the time difference; and estimating a lifetime of the second or fourth bump based on the load state.

In a semiconductor device where two or more semiconductor chips are stacked, since there is a large difference in linear expansion coefficient between a circuit board and the chip, a difference in amount of expansion and contraction (expansion-contraction amount) between the circuit board and the chip becomes large due to a change in temperature while in use of the semiconductor device. Therefore, due to a change in temperature, thermal stress is repetitively exerted on a bump, so that cracks gradually occur in an outer edge of the bump in the vicinity of an interface (boundary) between the bump and the circuit board or between the bump and the chip. The cracks gradually progress from the outer edge toward the center of the bump. Hereinafter, a state where cracks occur in a bump and a state where cracks completely progress so that a circuit is broken are collectively referred to as damage. In addition, as described later, the damage may be defined in correspondence to predetermined electrical characteristics of a bump, for example. Herein, the electrical characteristic denotes a characteristic value, for example, an electrical resistance value, a voltage value, a current value, and the like.

In the case where the stiffness (bending stiffness) of the circuit board is relatively large, the difference in amount of expansion and contraction cannot be eliminated by bending the entire semiconductor device. Therefore, thermal stress (shear force) mainly occurs in the bump between the circuit board and the lowermost-layer chip in the in-plane direction of the circuit board or the chip so as to prevent expansion and contraction. On the other hand, in the case where the stiffness (bending stiffness) of the circuit board is relatively small, the difference in amount of expansion and contraction can be eliminated by bending the entire semiconductor chip. However, as a result, thermal stress (tension stress or compression stress) mainly occurs in the bump between the chips stacked on the lowermost-layer chip in the stacking direction. In addition, among a plurality of the bumps provided between the circuit board and the chip or between the chips, larger thermal stress occurs in the bump (Y) of which the distance from the peripheral portion of the chip (or circuit board) is (relatively) short than in the bump (X) of which the distance from the peripheral portion is (relatively) long. Therefore, when the bumps are damaged, the bump (Y) is first damaged, and then the bump (X) is damaged.

In a semiconductor device of an embodiment to be described hereinafter, cracks of at least one bump which is in a peripheral portion and in an area where mainly shear stress is dominated as thermal stress and cracks of at least one bump which is in the peripheral portion and in an area where mainly tension and compression stress are dominated are detected, so that it is possible to detect the cracks occurring in the bump while in use of the semiconductor device at an early time irrespective of stiffness of a circuit board or packaging conditions of the semiconductor device.

Hereinafter, embodiments will be described with reference to the drawings. In the drawings, the same reference numerals denote the same or similar components.

### First Embodiment

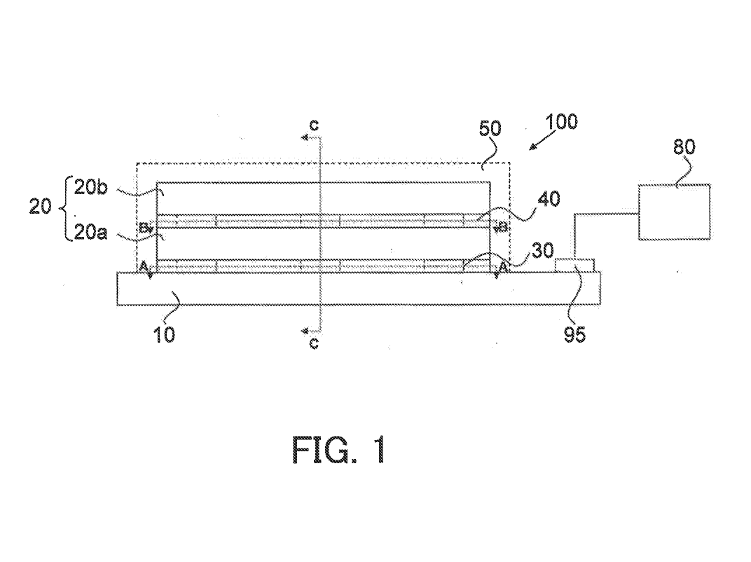

FIG. 1 is a diagram illustrating a semiconductor device 100 of a first embodiment.

The semiconductor device 100 is configured to include a stacked semiconductor chip 20 which is formed by stacking a plurality of semiconductor chips on a surface of circuit board 10 such as an interposer in a stacking direction (upwards in the figure). The stacked semiconductor chip 20 is configured to include a plurality of first semiconductor chips 20a which include a lowermost-layer semiconductor chip and a plurality of second semiconductor chips 20b which are stacked above the first semiconductor chips 20a.

The circuit board 10 and the first semiconductor chip 20a are interconnected through a first interconnection unit 30, and two of the first semiconductor chips 20a are interconnected through a first interconnection unit 30. The first semiconductor chip 20a and the second semiconductor chip 20b are interconnected through a second interconnection unit 40, and two of the second semiconductor chips 20b are interconnected through a second interconnection unit 40. In other words, the first interconnection units 30 are provided in a gap between the circuit board 10 and the first semiconductor chip 20a and in a gap between two of the first semiconductor chips 20a. The second interconnection units 40 are provided in a gap between the first semiconductor chip 20a and the second semiconductor chip 20b and in a gap between two of the second semiconductor chips 20b. The stacked semiconductor chip 20 which is stacked above the circuit board 10 is sealed with a package 50 made of a mold resin or the like which covers the surrounds (the side surfaces and the uppermost surface) of the stacked semiconductor chip 20.

For simplification, FIG. 1 illustrates an example where the stacked semiconductor chip 20 is configured to include one first semiconductor chip 20a and one second semiconductor chip 20b. In addition, for clarification of the internal configuration, the package 50 is indicated by a dotted line.

The circuit board 10 is a board where circuits such as printed wiring are formed on the surface (or internal portion) of the circuit board 10. As the circuit board 10, for example, a glass epoxy board, a ceramic board, a build-up multilayered board including a core layer and a build-up layer, or the like may be used. The circuit board 10 is configured to include a connector 95 which is provided in a portion of the circuit board 10 to communicate signals with external units.

The first and second semiconductor chips 20a and 20b are components having elements such as memories including circuits on surfaces (or inner portions) of the elements. As a material for the first and second semiconductor chips 20a and 20b, for example, a silicon (Si) wafer or the like may be used.

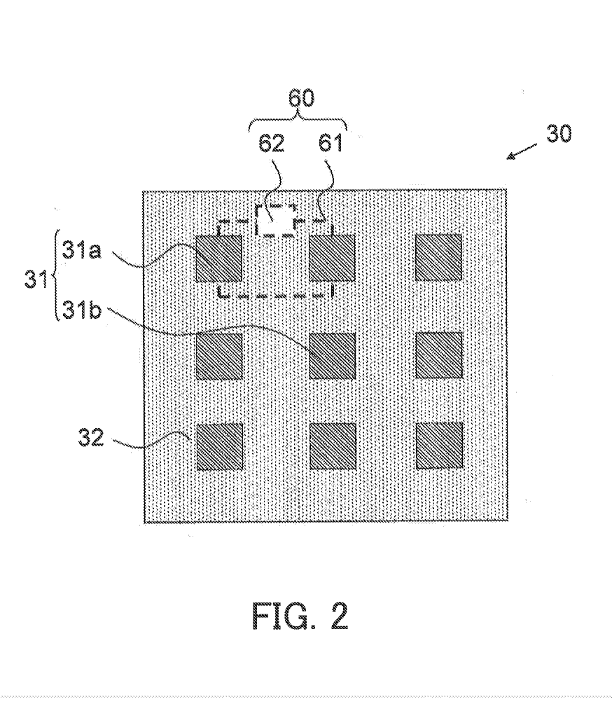

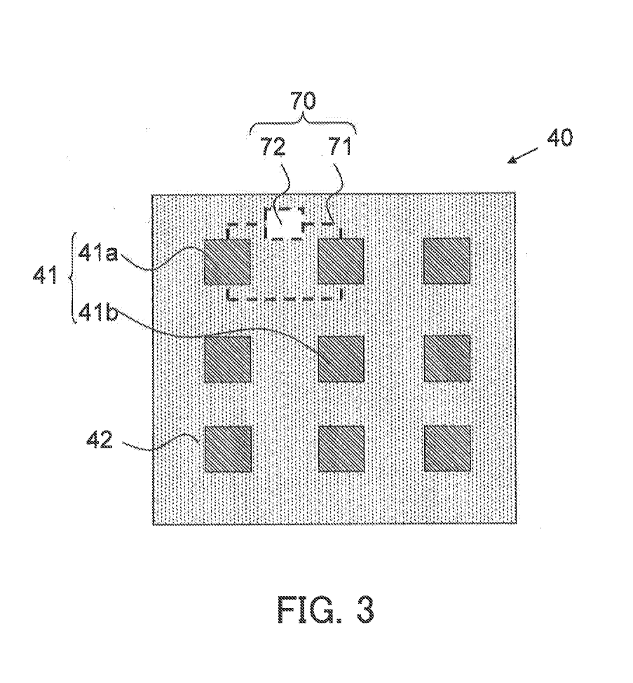

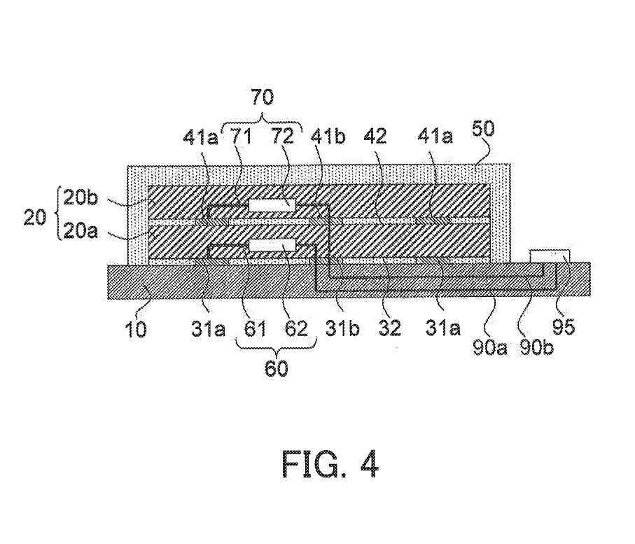

FIG. 2 is a cross-sectional diagram of the semiconductor device 100 taken along line A-A of FIG. 1. FIG. 3 is a cross-sectional diagram of the semiconductor device 100 taken along line B-B of FIG. 1. FIG. 4 is a cross-sectional diagram of the semiconductor device 100 taken along line C-C of FIG. 1.

As illustrated in FIG. 2, the first interconnection unit 30 is configured to include two or more conductive bumps 31 which are provided in the gap between the circuit board 10 and the first semiconductor chip 20a. The bumps 31 include first bumps 31a including bumps which are located in the peripheral portion of the first semiconductor chip 20a, that is, in the outermost sides within the surface of the first semiconductor chip 20a and second bumps 31b excluding the first bumps 31a. In addition, the first interconnection unit 30 is configured to include an underfill resin 32 which fills the space between the bumps 31 if necessary.

As illustrated in FIG. 3, the second interconnection unit 40 is configured to include two or more conductive bumps 41 which are provided in the gap between the first semiconductor chip 20a and the second semiconductor chip 20b. The bumps 41 include third bumps 41a including bumps which are located in the peripheral portion of the second semiconductor chip 20b, that is, in the outermost sides within the surface of the second semiconductor chip 20b and fourth bumps 41b excluding the third bumps 41a. In addition, the second interconnection unit 40 is configured to include an underfill resin 42 which fills the space between the bumps 41 if necessary.

As a material for the bumps 31 and 41, for example, a solder material having various compositions, a microbump made of an intermetallic compound, a copper pillar, or the like may be used. In addition, for simplification, herein, an example where the 3×3 (total 9) bumps 31 and the 3×3 (total 9) bumps 41 are provided in lattice shapes within the corresponding surfaces is illustrated. In addition, in the embodiment, the eight first bumps 31a and the eight third bumps 41a located in the peripheral portions are configured as dummy bumps which do not serve as signal lines between the chips in the stacked semiconductor chip 20, and the one second bump 31b and the one fourth bump 41b located at the centers are configured as bumps which serve as signal lines between the chips in the stacked semiconductor chip 20.

In the case where a plurality of the first semiconductor chips 20a are stacked and a plurality of the second semiconductor chips 20b are stacked, at least one first bump 31a may be provided as a dummy bump in any one of the gap between the circuit board 10 and the first semiconductor chip 20a and the gap between two of the first semiconductor chips 20a. In addition, at least one third bumps 41a may be provided as a dummy bump in any one of the gap between the first semiconductor chip 20a and the second semiconductor chip 20b and the gap between two of the second semiconductor chips 20b. In addition, as for a boundary between the first semiconductor chip 20a and the second semiconductor chip 20b, through experiment, and simulation of structural analysis, or the like in advance, a chip within an area where shear stress is dominated may be set in advance as the first semiconductor chip 20a, and a chip within an area where tension and compression stress are dominated may be set in advance as the second semiconductor chip 20b.

A first detection circuit 60 is configured to include a first connection unit 61 and a first detection unit 62. The first connection unit 61 is wiring which is connected to the first bump 31a and the first detection unit 62 to electrically connect the first bump 31a and the first detection unit 62. In other words, the first connection unit 61 and the first detection unit 62 form a closed direct current (DC) circuit through the first bump 31a. The first connection unit 61 is included in a portion of a circuit of the first semiconductor chip 20a (or a portion of a circuit of the circuit board 10). Similarly to the first connection unit 61, the first detection unit 62 is included in a portion of a circuit of the first semiconductor chip 20a (or a portion of a circuit of the circuit board 10).

In FIG. 2, a closed DC circuit is formed by connecting two of the first bumps 31a and the first detection unit 62 in the same gap through the first connection unit 61. In addition, the number of first bumps 31a of the first detection circuit 60 may be one or larger than three. In the case where the first semiconductor chip 20a is configured with multiple layers, two or more first bumps 31a in different gaps may be connected.

The first detection unit 62 detects an electrical resistance value (electrical characteristic) of the first bump 31a. Since the first detection circuit 60 is a closed DC circuit, the first detection unit 62 measures an electrical resistance value of the path connected to the first bump 31a and the first connection unit 61 to detect the electrical resistance value substantially as an electrical resistance value of the first bump 31a. The electrical resistance value of the first bump 31a is compared with a predefined electrical resistance value (first threshold value) at the time of damage, so that the damage of the first bumps 31a is detected at the time point when the electrical resistance value exceeds the first threshold value. In this case, since the first connection unit 61 is a portion of the first detection circuit 60, the first detection unit 62 may detect the damage of the first connection unit 61 in addition to the damage of the first bump 31a. When the first detection unit 62 detects the damage of the first bump 31a (or the first connection unit 61), the first detection unit 62 generates a damage signal (first signal) indicating the damage of the first bump 31a (or the first connection unit 61).

In addition, cracks occur in the first bump 31a in the direction from the outer edge of the first bump 31a to the center in the interface between the first bump 31a and the circuit board 10 or between the first bump 31a and the first semiconductor chip 20a. The first bump 31a is provided on the circuit board 10 or the first semiconductor chip 20a through an electrode pad (not illustrated) which is a portion of the circuit board 10 or the first semiconductor chip 20a. In addition, the first connection unit 61 of the first detection circuit 60 is connected to two different points of the electrode pad. Therefore, preferably, in order to easily detect the damage of the first bump 31a in accordance with a change in electrical resistance value of the first bump 31a, for example, an electrically insulating unit may be formed at the center of the electrode pad, and the first connection unit 61 may be connected to two points of the outer edge of the electrode which interpose the electrically insulating unit.

As illustrated in FIG. 4, the first detection unit 62 is electrically connected to the connector 95 of the circuit board 10 through a first signal line 90a. The first detection unit 62 outputs the first signal to external components through the first signal line 90a. In addition, the first signal line 90a is included, for example, in a portion of a circuit of the first semiconductor chip 20a and a portion of a circuit of the circuit board 10 to electrically connect the first detection unit 62 and the connector 95 through the second bump 31b.

A second detection circuit 70 is configured to include a second connection unit 71 and a second detection unit 72. The second connection unit 71 is wiring which is connected to the third bump 41a and the second detection unit 72 to electrically connect the third bump 41a and the second detection unit 72. In other words, the second connection unit 71 and the second detection unit 72 form a closed DC circuit through the third bump 41a. The second connection unit 71 is included in a portion of a circuit of the second semiconductor chip 20b. Similarly to the second connection unit 71, the second detection unit 72 is included in a portion of a circuit of the second semiconductor chip 20b (or a portion of a circuit of the circuit board 10).

In FIG. 3, a closed DC circuit is formed by connecting two third bumps 41a and the second detection unit 72 in the same gap through the second connection unit 71. In addition, the number of the third bumps 41a of the second detection circuit 70 may be one or larger than three. In the case where the second semiconductor chip 20b is configured with multiple layers, two or more third bumps 41a in different gaps may be connected.

The second detection unit 72 detects an electrical resistance value (electrical characteristic) of the third bump 41a. Since the second detection circuit 70 is a closed DC circuit, the second detection unit 72 measures an electrical resistance value of the path connected to the third bump 41a and the second connection unit 71 to detect the electrical resistance value substantially as an electrical resistance value of the third bump 41a. The electrical resistance value of the third bump 41a is compared with a predetermined electrical resistance value (second threshold value) at the time of damage, so that the damage of the third bump 41a is detected at the time point when the electrical resistance value exceeds the second threshold value. In this case, since the second connection unit 71 is a portion of the second detection circuit 70, the second detection unit 72 may detect the damage of the second connection unit 71 in addition to the damage of the third bump 41a. When the second detection unit 72 detects the damage of the third bump 41a (or the second connection unit 71), the second detection unit 72 generates a damage signal (second signal) indicating the damage of the third bump 41a (or the second connection unit 71). In addition, the first and second threshold values may be equal to or different from each other.

In addition, cracks occurs in the third bump 41a in the direction from the outer edge of the third bump 41a to the center in the interface between the third bump 41a and the second semiconductor chip 20b. The third bump 41a is provided on the second semiconductor chip 20b through an electrode pad (not illustrated) which is a portion of the second semiconductor chip 20b. In addition, the second connection unit 71 of the second detection circuit 70 is connected to two different points of the electrode pad. Therefore, preferably, in order to easily detect the damage of the third bump 41a in accordance with a change in electrical resistance value of the third bump 41a, for example, an electrically insulating unit may be formed at the center of the electrode pad, and the second connection unit 71 may be connected to two points of the outer edge of the electrode pad which interposes the electrically insulating unit.

As illustrated in FIG. 4, the second detection unit 72 is electrically connected to the connector 95 of the circuit board 10 through a second signal line 90b. The second detection unit 72 outputs the second signal to external components through the second signal line 90b. In addition, the second signal line 90b is included, for example, in a portion of a circuit of the first semiconductor chip 20a, a portion of a circuit of the second semiconductor chip 20b, and a portion of a circuit of the circuit board 10 to electrically connect the second detection unit 72 and the connector 95 through the second bump 31b and the fourth bump 41b.

In FIG. 1, an output unit 80 is a display apparatus or an alarm apparatus which is electrically connected to the first detection unit 62 and the second detection unit 72 through the connector 95. The output unit 80 receives the first signal from the first detection unit 62 or receives the second signal from the second detection unit 72 and notifies a user using the semiconductor device 100 of the damage of the first bump 31a or the third bump 41a by display or alarm. In this case, the user may be notified of the damage of the first bump 31a or the third bump 41a as a disorder of the semiconductor device 100. In addition, in the embodiment, the semiconductor device 100 includes the output unit 80.

In a method of manufacturing the semiconductor device 100, the chips of the stacked semiconductor chip 20 are manufactured by using a general semiconductor manufacturing process, and the semiconductor device 100 may be manufactured by performing flip chip connection between the chips.

In the semiconductor device 100 of the embodiment, at least one first bump 31a is provided in the area which is in the vicinity of the lowermost layer and the vicinity of the peripheral portion of the stacked semiconductor chip 20, that is, that area where the shear stress is dominated, and at least one third bump 41a is provided in the area which is in the intermediate layer and the vicinity of the peripheral portion of the stacked semiconductor chip 20, that is, the area where the tension and compression stress are dominated. Therefore, cracks occurring in the bumps while in use of the semiconductor device can be detected at an early time irrespective of the stiffness of the circuit board 10 or the packaging condition.

In addition, the first bumps 31a and the third bumps 41a are provided in the outermost side of the peripheral portion where the stronger stress is exerted in comparison to the inner portion. Therefore, it is possible to detect cracks occurring in the bumps at an earlier time.

In addition, as described above, since there is a large difference in linear expansion coefficient between the circuit board 10 and the first semiconductor chip 20a, a difference in amount of expansion and contraction between the circuit board 10 and the first semiconductor chip 20a in accordance with a change in temperature is remarkably larger than a difference in amount of expansion and contraction between the semiconductor chips. In addition, since a higher current tends to flow in the circuit board 10 serving as an interposer or the like than in the semiconductor chip, it is considered that the temperature of the circuit board 10 is higher than that of the semiconductor chip. For these reasons, the difference in amount of expansion and contraction between the circuit board 10 and the first semiconductor chip 20a is further increased. Therefore, the first bumps 31a are provided in the gap between the circuit board 10 and the first semiconductor chip 20a where the largest difference in amount of expansion and contraction in accordance with a change in temperature occurs in the semiconductor device 100. Accordingly, cracks occurring in the bumps can be detected at an earlier time.

In addition, the first detection unit 62 and the second detection unit 72 may measure a voltage value or a current value instead of the electrical resistance value. In a constant voltage circuit, as an electrical resistance value is increased, a current is decreased. Therefore, in this case, the first detection unit 62 and the second detection unit 72 measure the current value of the circuit, so that the damage of each bump can be detected at the time point when the current value is lower than a predetermined current value at the time of damage. In addition, in a constant voltage circuit, as an electrical resistance value is increased, a voltage is increased. Therefore, in this case, the first detection unit 62 and the second detection unit 72 measure the voltage value of each bump, so that the damage of each bump can be detected at the time point when the voltage value exceeds a predetermined voltage value at the time of damage.

In addition, since the first and third bumps 31a and 41a are dummy bumps which do not serve as signal lines, it is possible to detect damage of the dummy bumps before damage of the second and fourth bumps 31b and 41b which serve as signal lines which are necessary in terms of functions of the semiconductor device 100. Accordingly, it is possible to notify a user of a symptom of disorder of the semiconductor device 100.

In addition, although the components including the output unit 80 are included in the semiconductor device 100 in the embodiment, the components including the connector 95 may be configured to be included in the semiconductor device 100, and the output unit 80 connected to the connector 95 may be configured as an external component of the semiconductor device 100.

### Second Embodiment

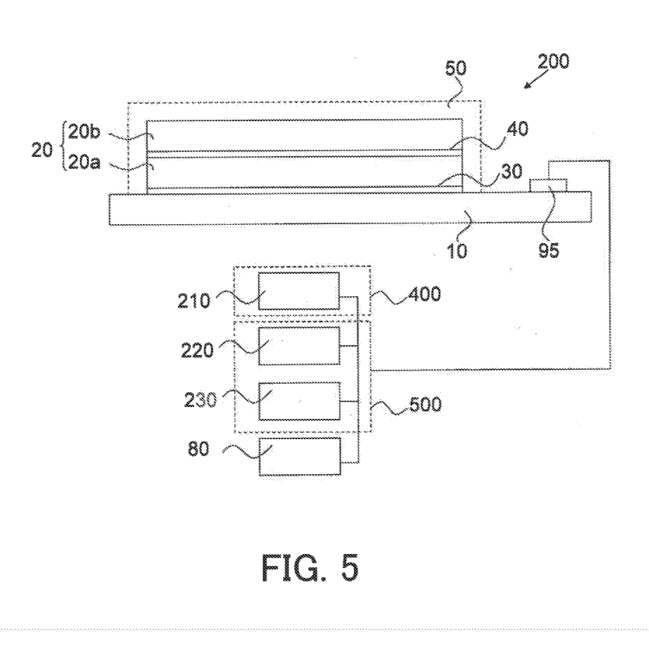

FIG. 5 is a diagram illustrating a semiconductor device 200 of a second embodiment. The same components as those the semiconductor device 100 of FIG. 1 are denoted by the same reference numerals, and detail description will not be repeated. In the semiconductor device 200, the first signal from the first detection unit 62 and the second signal from the second detection unit 72 are used to estimate a load state in the semiconductor device 200 and to estimate a lifetime of the semiconductor device 200.

The semiconductor device 200 includes a storage unit 210, a load estimation unit 220, and a lifetime estimation unit 230 in addition to the semiconductor device 100 of FIG. 1. As the storage unit 210, a storage apparatus 400 such as a memory is used. As the load estimation unit 220 and the lifetime estimation unit 230, an arithmetic processing unit 500 such as a CPU is used. The load estimation unit 220 is electrically connected to the first detection unit 62 and the second detection unit 72 through the connector 95.

A deformation state (for example, magnitude of bending) of the semiconductor device 200 and a stress state of the semiconductor device 200 can be estimated based on the first and second signals. In the description hereinafter, the deformation state and the stress state are collectively referred to as a load state. In addition, when a state where bending does not occur in, for example, the semiconductor device 200 (thermal stress is not exerted) is set as a reference state, the deformation state may be defined as an amount of displacement from positions (reference positions) of the second bump 31b and the fourth bump 41b in the reference state. In addition, the stress state may be defined as stress occurring in, for example, the second bump 31b and the fourth bump 41b.

Hereinafter, a principle of estimation of the load state of the semiconductor device 200 based on the first and second signals will be described.

As described above, since there is generally a large difference in linear expansion coefficient between the stacked semiconductor chip 20 and the circuit board 10, a thermal stress occurs between the stacked semiconductor chip 20 and the circuit board 10 in accordance with a change in temperature.

In the case where the bending stiffness of the circuit board 10 is small, large bending occurs in the structure. Accordingly, the shear stress in the vicinity of the lowermost layer of the stacked semiconductor chip 20 is decreased, and the tension and compression stress occurring in the peripheral portion of the intermediate layer of the stacked semiconductor chip 20 are dominated. On the other hand, in the case where the bending stiffness of the circuit board 20 is large, small bending occurs in the structure. Accordingly, the tension and compression stress occurring in the peripheral portion of the intermediate layer of the stacked semiconductor chip 20 are decreased, and the shear stress in the vicinity of the lowermost layer of the stacked semiconductor chip 20 is dominated.

Therefore, it can be considered that the first detection unit 62 provided in the area which is in the vicinity of the lowermost layer of the stacked semiconductor chip 20, that is, the area where the shear stress is dominated detects the damage of the first bump 31a which is damaged due to the shear stress to generate the first signal. In addition, it can be considered that the second detection unit 72 provided in the area which is in the intermediate layer of the stacked semiconductor chip 20, that is, the area where the tension and compression stress are dominated detects the damage of the third bump 41a which is damaged due to the tension and compression stress to generate the second signal. In the embodiment, the load state is estimated based on a time difference between the times of damage of the first and third bumps 31a and 41a which are damaged due to different types of stress having different properties.

In this case, a correspondence relation between a time interval from the time of damage of the first bump 31a of which position is known to the time of damage of the third bump 41a of which position is known or a time interval from the time of damage of the third bump 41a to the time of damage of the first bump 31a and load states of the second and fourth bumps 31b and 41b excluding the first and third bumps 31a and 41a is investigated through experiment, and simulation of structural analysis, or the like in advance. In other words, the correspondence relation includes a relation between the time interval between the time of damage of the first bump 31a of which position is known and the time of damage of the third bump 41a and the load states of all the second and fourth bumps 31b and 41b which are in correspondence to the time interval. The time interval has a positive value, for example, in the case where the first bump 31a is damaged earlier and the third bump 41a is damaged later and a negative value in the case where the third bump 41a is damaged earlier and the first bump 31a is damaged later. In addition, the correspondence relation may be configured by using, for example, a table or by using, for example, a function having the time interval as a variable. The correspondence relation is stored in the storage unit 210 in advance.

The load estimation unit 220 receives the first signal and the second signal and calculates a time difference between reception times of the first and second signals. The load estimation unit 220 estimates the load state of the semiconductor device 200, more specifically, the load states of the second and fourth bumps 31b and 41b based on the time difference. In addition, at this time, the load states of the second and fourth bumps 31b and 41b may be individually estimated. In addition, the load states of several second bumps 31b and the load states of several fourth bumps 41b are collected, and the average state of these load states may be estimated.

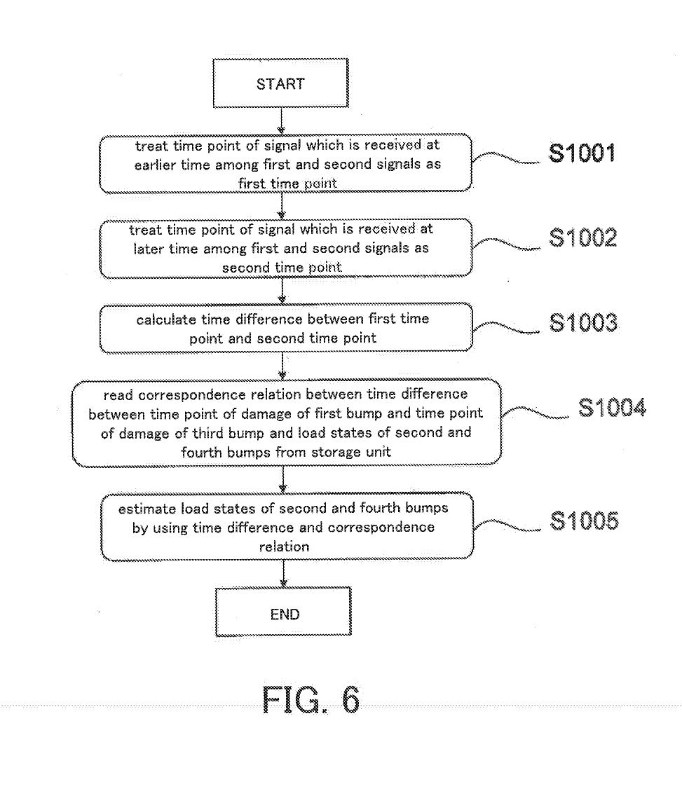

FIG. 6 is a flowchart illustrating operations of the load estimation unit 220.

In S1001, the time point (first time point) of the signal which is received at the earlier time among the first and second signals is temporarily stored in the storage unit 210. In the case where the received signal is the first signal, the first time point is treated as the time point of damage of the first bump 31a, and in the case where the received signal is the second signal, the first time point is treated as the time point of damage of the third bump 41a. In addition, a first identification signal indicating which one of the first and second signals is received is generated and stored in the storage unit 210.

In S1002, the time point (second time point) of the signal which is received at the later time among the first and second signals is temporarily stored in the storage unit 210. In the case where the received signal is the first signal, the second time point is treated as the time point of damage of the first bump 31a, and in the case where the received signal is the second signal, the second time point is treated as the time point of damage of the third bump 41a. In addition, a second identification signal indicating which one of the first and second signals is received is generated and stored in the storage unit 210.

In S1003, the first time point, the first identification signal, the second time point, and the second identification signal are read from the storage unit 210, and a time difference between the reception times of the first and second signals is calculated based on the read first time point, the read first identification signal, the read second time point, and the read second identification signal. At this time, the order of signal reception can be identified, for example, in accordance with a positive or negative sign of the time difference. In other words, in the case where the first signal is received at the earlier time and the second signal is received at the later time, the sign of the time difference is set to positive with reference to the first and second identification signals, and in the case where the second signal is received at the earlier time and the first signal is received at the later time, the sign of the time difference is set to negative. In this manner, the time difference including the sign is treated as the time interval between the time point of damage of the first bump 31a and the time point of damage of the third bump 41a.

In S1004, the correspondence relation between the time difference between the time point of damage of the first bump 31a and the time point of the damage of the third bump 41a and the load states of the second and fourth bumps 31b and 41b is read from the storage unit 210.

In S1005, the load states of the second and fourth bumps 31b and 41b are estimated by using the time difference calculated in S1003 and the correspondence relation obtained in S1004. In other words, in the case where the correspondence relation is a table, the load state at the time of the time interval corresponding to the time difference calculated in S1003 is read from the table, and the read load state is treated as an estimated value. In addition, in the case where the correspondence relation is a function, the load state is calculated by substituting the calculated time difference as the time interval into the function, and the calculated load state is treated as an estimated value.

In addition, although S1004 and S1005 are described as different steps herein, the load states of the second and fourth bumps 31b and 41b may be estimated by directly referring to the correspondence relation stored in the storage unit 210 without reading the correspondence relation from the storage unit 210.

The lifetime estimation unit 230 estimates the lifetime of the second and fourth bump 31b and 41b based on the estimated values of the load states of the second and fourth bump 31b and 41b estimated by the load estimation unit 220. In addition, at this time, the lifetimes of the second and fourth bumps 31b and 41b may be individually estimated. In addition, the lifetimes of several second bumps 31b and the lifetimes of several fourth bumps 41b are collected, and the average lifetime of these lifetimes may be estimated. Herein, the lifetime may denote a time remaining until the second and fourth bumps 31b and 41b are damaged or the number of occurrence cycles of stress until the second and fourth bumps 31b and 41b are damaged.

As a method of estimating the lifetimes of the second and fourth bumps 31b and 41b, well-known methods (for example, Japanese Patent Application Laid-Open No. 2010-73795) may be used, and the description is not presented herein.

The output unit 80 receives the lifetimes of the second and fourth bumps 31b and 41b estimated by the lifetime estimation unit 230 and notifies the user using the semiconductor device 200 of the lifetimes of the second and fourth bumps 31b and 41b by display.

In addition, the storage unit 210, the load estimation unit 220, and the lifetime estimation unit 230 may be provided as a lifetime estimation apparatus (that is, the storage apparatus 400 and the arithmetic processing unit 500), which is electrically connected to the semiconductor device 200 through the connector 95, separately from the semiconductor device 200. In addition, the output unit 80 may be provided as a display apparatus, which is electrically connected to the lifetime estimation apparatus, separately from the semiconductor device 200.

In the semiconductor device 200 of the embodiment, the lifetimes of the second and fourth bumps 31b and 41b are estimated in accordance with the damage of a portion of the bumps, that is, the damage of at least one first bump 31a and at least one third bump 41a, so that the user can be urged to stop or repair the semiconductor device 200 before the semiconductor chip 200 is in trouble.

(Modification)

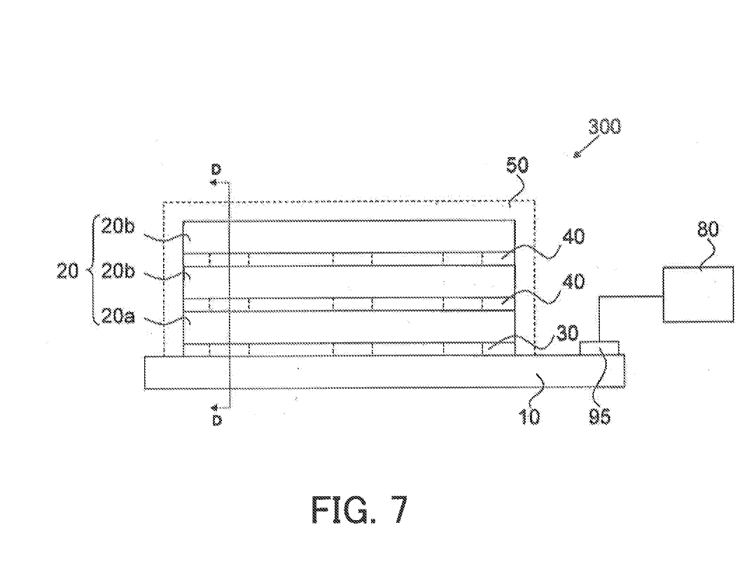

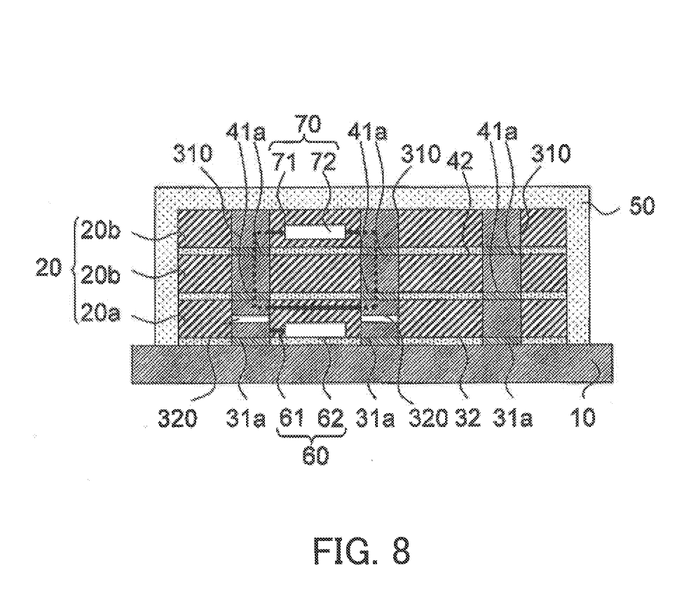

FIG. 7 is a diagram illustrating a semiconductor device 300 of a modification. In the semiconductor device 300 illustrated in FIG. 7, one first semiconductor chip 20a and two second semiconductor chips 20b are stacked. FIG. 8 is a cross-sectional diagram of the semiconductor device 300 taken along line D-D of FIG. 7. The same components as those the semiconductor devices 100 and 200 are denoted by the same reference numerals, and detail description will not be repeated. In addition, the connector 95, the first signal line 90a, and the second signal line 90b are not illustrated in FIG. 8.

As illustrated in FIG. 8, the semiconductor device 300 is configured to include a plurality of through-vias 310 which penetrate at least a portion of the first semiconductor chip 20a and the second semiconductor chips 20b in the stacking direction.

The through-via 310 is a conductive electrode which partially includes a first bump 31a and third bumps 41a. The through-via 310 electrically connects the chips of the stacked semiconductor chip 20 through the first bump 31a and the third bumps 41a.

The through-via 310 includes an insulating unit 320 which is provided between the first bump 31a and the third bump 41a to electrically insulate the first bump 31a and the third bump 41a. As the insulating unit 320, an electrically insulating member may be used, or a gap may be used.

In a second detection circuit 70, a second connection unit 71 and a second detection unit 72 form a closed DC circuit through the two through-vias 310. In addition, in the DC circuit, two third bumps 41a are provided in one through-via 310. In other words, in accordance with the configuration, the damage of any one of a plurality of the third bumps 41a, the second connection unit 71, and the through-via 310 can be detected by the one second detection unit 72. Although the second detection circuit 70 is exemplified herein, the same description can be made with respect to the first detection circuit 60.

In a method of manufacturing the semiconductor device 300, through-holes are formed in the chips of the stacked semiconductor chip 20 by using masking, photolithography, and etching processes. The through-holes are filled with polysilicon. The semiconductor device 300 may be manufactured by performing flip chip connection between the chips. In this case, the insulating unit 320 can be formed by using a method where a through-hole is not formed in a localized area of a specific chip layer, a method where a bump is not formed in a localized area when chips are connected to each other through flip chip connection, or the like.

In the semiconductor device 300 of the embodiment, it is possible to detect damage of bumps or the like over a range wider than the inner portion of the semiconductor chip 300 by using a minimally-configured detection circuit, that is, a simple configuration. Accordingly, since damage situation can be checked over the wide range, it is possible to detect cracks occurring in the bumps at an earlier time.

In addition, since the through-via 310 is configured to include the insulating unit 320, for example, in the case where the first detection unit 60 or the second detection unit 70 forms a DC circuit over multiple layers, a range of a path for damage detection of the first detection unit 60 and a range of a path for damage detection of the second detection unit 70 are electrically insulated from each other. Therefore, it is possible to improve accuracy of path damage detection of the first detection unit 60 or the second detection unit 70.

In accordance with a semiconductor device of at least one embodiment explained above, it is possible to detect cracks occurring in the bumps at an earlier stage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a circuit board;
a plurality of semiconductor chips stacked above the circuit board;
a first bump and a second bump provided in either a gap between the circuit board and the semiconductor chip or a gap between the two semiconductor chips, the second bump being more distant from a peripheral portion of the semiconductor chip than the first bump;
a third bump and a fourth bump provided in any of gaps other than the gap in which the first and second bumps are provided among the gaps including the gap between the circuit board and the semiconductor chip and the gap between the two semiconductor chips, the fourth bump being more distant from a peripheral portion of the semiconductor chip than the third bump;
a first detection unit electrically connected to the first bump to detect damage of the first bump and to generate a first signal indicating the damage of the first bump; and
a second detection unit electrically connected to the third bump to detect damage of the third bump and to generate a second signal indicating the damage of the third bump.

2. The semiconductor device according to claim 1,
wherein the plurality of semiconductor chips include a plurality of first semiconductor chips stacked above the circuit board and a plurality of second semiconductor chips stacked above the first semiconductor chips,
wherein the first and second bumps are provided in either a gap between the circuit board and the first semiconductor chip or a gap between two of the first semiconductor chips, and
wherein the third and fourth bumps are provided in either a gap between the first and second semiconductor chips or a gap between two of the second semiconductor chips.

3. The semiconductor device according to claim 1,
wherein the plurality of semiconductor chips include a first semiconductor chip provided above the circuit board and a second semiconductor chip provided above the first semiconductor chip,
wherein the first and second bumps are provided in a gap between the circuit board and the first semiconductor chip, and
wherein the third and fourth bumps are provided in a gap between the first and second semiconductor chips.

4. The semiconductor device according to claim 1, further comprising a resin filling any of the gaps.

5. The semiconductor device according to claim 1, further comprising a through-via penetrating the plurality of semiconductor chips, the through-via partially including the first and third bumps.

6. The semiconductor device according to claim 5, wherein the through-via is configured to include an insulating unit provided between the first and third bumps to electrically isolate the first and third bumps.

7. The semiconductor device according to claim 1,
wherein the first detection unit measures at least a first electrical characteristic of the first bump and compares the first electrical characteristic with a first threshold value indicating an electrical characteristic at a time of damage of the first bump to detect the damage of the first bump, and
wherein the second detection unit measures at least a second electrical characteristic of the third bump and compares the second electrical characteristic with a second threshold value indicating an electrical characteristic at a time of damage of the third bump to detect the damage of the third bump.

8. The semiconductor device according to claim 7, wherein each of the first and second electrical characteristics is any one of an electrical resistance value, a current value, and a voltage value.

9. The semiconductor device according to claim 1, further comprising:
a first connection unit to electrically connect the first bump and the first detection unit; and
a second connection unit to electrically connect the third bump and the second detection unit,
wherein the first detection unit further detects damage of the first connection unit, and the second detection unit further detects damage of the second connection unit.

10. The semiconductor device according to claim 1, further comprising:
a first signal line electrically connected to the first detection unit;
a second signal line electrically connected to the second detection unit; and
a load estimation unit electrically connected to the first and second signal lines to receive the first and second signals through the first and second signal lines and to calculate the difference between reception times of the first and second signals to estimate a load state of the second or fourth bump based on the time difference.

11. The semiconductor device according to claim 10, further comprising a lifetime estimation unit estimating a lifetime of the second or fourth bump based on the load state.

12. The semiconductor device according to claim 10, wherein the load state denotes an amount of displacement from a predetermined reference position of the second or fourth bump or stress exerted on the second or fourth bump.

13. The semiconductor device according to claim 11, wherein the lifetime denotes a time remaining until the second or fourth bump is damaged.

14. The semiconductor device according to claim 11, wherein the lifetime denotes a number of occurrence cycles of stress until the second or fourth bump is damaged.

15. The semiconductor device according to claim 1, further comprising an output unit receiving the first or second signal, and notifying a disorder of the semiconductor device by display or alarm.

16. The semiconductor device according to claim 11, further comprising an output unit displaying the lifetime of the second or fourth bump.

17. An apparatus of estimating a lifetime of a semiconductor device, the device includes a circuit board, a plurality of semiconductor chips stacked above the circuit board, a first bump and a second bump provided in either a gap between the circuit board and the semiconductor chip or a gap between the two semiconductor chips, wherein the second bump is more distant from a peripheral portion of the semiconductor chip than the first bump, a third bump and a fourth bump provided in any of gaps other than the gap in which the first and second bumps are provided among the gaps including the gap between the circuit board and the semiconductor chip and the gap between the two semiconductor chips, wherein the fourth bump is more distant from a peripheral portion of the semiconductor chip than the third bump, a first detection unit electrically connected to the first bump to detect damage of the first bump and to generate a first signal indicating the damage of the first bump, and a second detection unit electrically connected to the third bump to detect damage of the third bump and to generate a second signal indicating the damage of the third bump, the apparatus comprising;
a load estimation unit configured to receive a first signal indicating damage of the first bump and a second signal indicating damage of the third
